(19) United States
(12) Patent Application Publication
(10) Pub. No.: US 2009/0115533 A1
(43) Pub. Date: May 7, 2009

(54) VOLTAGE CONTROLLED OSCILLATOR

(76) Inventor: Sang-June Kim, Gangnam-gu (KR)

Correspondence Address: SHERR & VAUGHN, PLLC, 620 HERNDON PARKWAY, SUITE 200, HERNDON, VA, 20170, US

(21) Appl. No.: 12/258,416

(22) Filed: Oct. 26, 2008

(30) Foreign Application Priority Data
Nov. 7, 2007 (KR) 10-2007-0112978

(51) Int. Cl. H03L 7/00

(52) U.S. Cl. 331/8

(57) ABSTRACT

A voltage controlled oscillator may include a plurality of inverting units connected in serial and connected between a first and a second voltage sources to produce an oscillating frequency. Each of the inverting units may have a first current source for producing a constant current that may determine an oscillating frequency, a switching inverter connected between the first voltage source and the first current source that may produce a current having a phase opposite to an output current from a preceding inverting unit, and a frequency adjuster that may control the oscillating frequency by charging and/or discharging the current from the inverting unit.

The present application claims priority under 35 U.S.C. 119 to Korean Patent Application No. 10-2007-0112978 (filed on Nov. 7, 2007), which is hereby incorporated by reference in its entirety.

### BACKGROUND

A voltage controlled oscillator (VCO) may provide a desired frequency using a voltage supplied from an outside source. A VCO may be used in an analog sound mixing device, a mobile communication terminal, and other devices. A VCO may generate pitches and waveforms in an audio system, and may generate primary sounds by creating a sine wave, a saw-tooth wave, a pulse wave, and a triangular wave. A VCO may be used in a phase locked loop (PLL) module of a mobile communication terminal and may allocate channels and may function as a local oscillator to convert a frequency into a radio frequency (RF) or an intermediate frequency (IF).

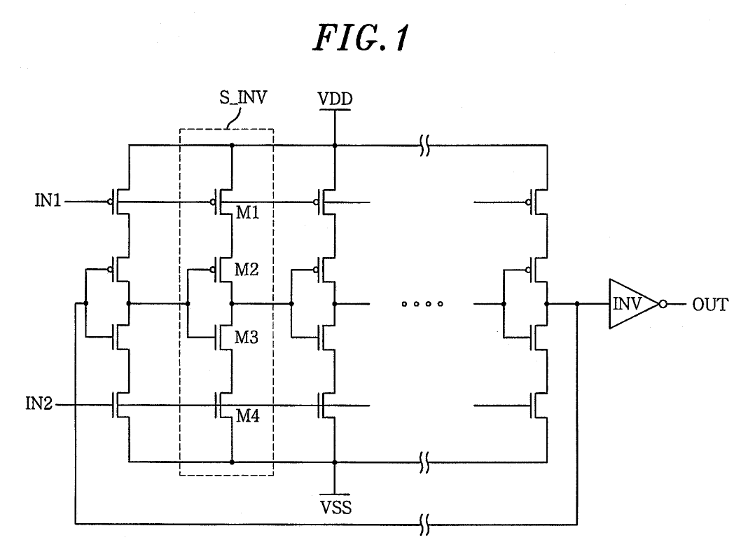

Example FIG. 1 illustrates a circuit diagram of a voltage controlled oscillator (VCO). Referring to example FIG. 1, a VCO may include an odd-number of depletion-mode inverting units S_INV and inverter INV. Inverter INV may invert an output signal from a last inverting unit S_INV and may produce an inverted output signal. Each inverting unit S_INV may include first, second, third, and fourth transistors M1, M2, M3, and M4. Second transistor M2 and third transistor M3 may function as an inverter and first transistor M1 and fourth transistor M4 may function as current sources. First transistor M1 and fourth transistor M4 may restrict a current to be supplied to second transistor M2 and third transistor M3. First transistor M1 and fourth transistor M4 may be supplied with current from first input terminal IN1 and second input terminal IN2, respectively. This may generate current flowing through inverting unit S_INV.

The following equation 1 may expresses a frequency of a voltage output from VCO as shown in FIG. 1.

$$F ( {V}_{S\_out} ) = \frac{{I}_{D}}{N \times C \times {V}_{DD}} \qquad Equation 1$$

In equation 1, I_{D} may be current flowing through inverting unit S_INV, N may be a number of inverting unit(s) S_INV provided in VCO, C may be a sum of parasitic capacitances at input terminals of transistors of inverting unit(s) S_INV, and V_{DD} may be a first voltage supplied to an oscillating unit. F(V_{S}_{_{—}}ₒᵤₜ) may be a frequency of an output voltage from VCO. A frequency may linearly vary in proportion to current I_{D} that may flow through inverting units S_INV, and may vary in inverse proportion to first voltage V_{DD}. However, a level of first voltage V_{DD} may easily be changed due to various factors. This change may bring a variation to frequency F (V_{S}_{_{—}}ₒᵤₜ) of an output voltage from VCO. Thus, VCO may be restricted to be used in a circuit requiring a constant output frequency due to the voltage change.

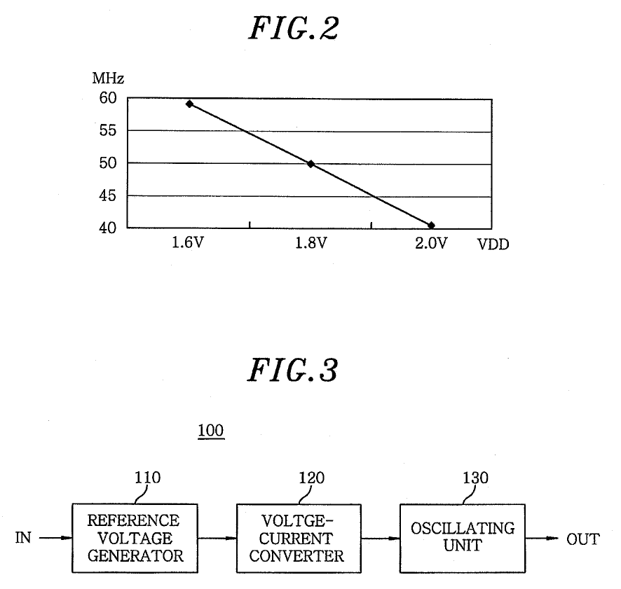

Example FIG. 2 illustrates a simulated waveform of an output frequency from VCO depending on a first voltage applied to VCO illustrated in example FIG. 1. The waveform of FIG. 2 may express frequencies of an output voltage from VCO when first voltage V_{DD} varies in a range between approximately 1.6 V to 2.0 V. Referring to example FIG. 2, when a level of an output voltage from VCO varies, a frequency of an output voltage from VCO may decrease from 60 MHz to 40 MHz. In other words, a frequency may vary by 10 MHz as a first voltage varies by 0.2 V. As a result, a variation range of the frequency may be very wide when first voltage V_{DD} varies. Due to a variation of the frequency, problems, such as jitter, may occur.

### SUMMARY

Embodiments relate to a voltage controlled oscillator (VCO). Embodiments relate to a VCO that may be capable of maintaining a constant frequency of an output voltage even when an applied voltage varies.

According to embodiments, a voltage controlled oscillator may maintain a substantially constant frequency of an output voltage from the voltage controlled oscillator even when a voltage supplied to the voltage controlled oscillator varies.

According to embodiments, a voltage controlled oscillator may include a plurality of inverting units connected in series and connected between first and second voltage sources to produce an oscillating frequency. According to embodiments, each of the inverting units may include at least one of the following. A first current source to produce a constant current determining the oscillating frequency. A switching inverter connected between the first voltage source and the first current source to produce a current having an opposite phase to the output current from a preceding inverting unit. A frequency adjuster to control the oscillating frequency by charging and/or discharging the current from the inverting unit.

According to embodiments, a voltage controlled oscillator may include a plurality of inverting units connected in series, which may produce an oscillating frequency. According to embodiments, each inverting unit may include at least one of the following. A first PMOS transistor electrically coupled between a first voltage source and a second voltage source. A first NMOS transistor electrically coupled between the first PMOS transistor and the second voltage source. A second NMOS transistor electrically coupled between the first NMOS transistor and the second voltage source. A second PMOS transistor electrically coupled between the first voltage source and an output terminal of a preceding inverting unit. A third NMOS transistor electrically coupled to the second NMOS transistor, and having a control electrode electrically coupled between the first PMOS transistor and the second PMOS transistor.

According to embodiments, even when a voltage supplied to the voltage controlled oscillator varies, a frequency of an output voltage may be maintained substantially constant.

### DRAWINGS

Example FIGS. 1 and 2 illustrate a circuit diagram of a voltage controlled oscillator (VCO) and a simulated waveform of frequency of a VCO depending on a voltage applied to the VCO shown in example FIG. 1.

Example FIG. 3 illustrates a block diagram of a voltage controlled oscillator, according to embodiments.

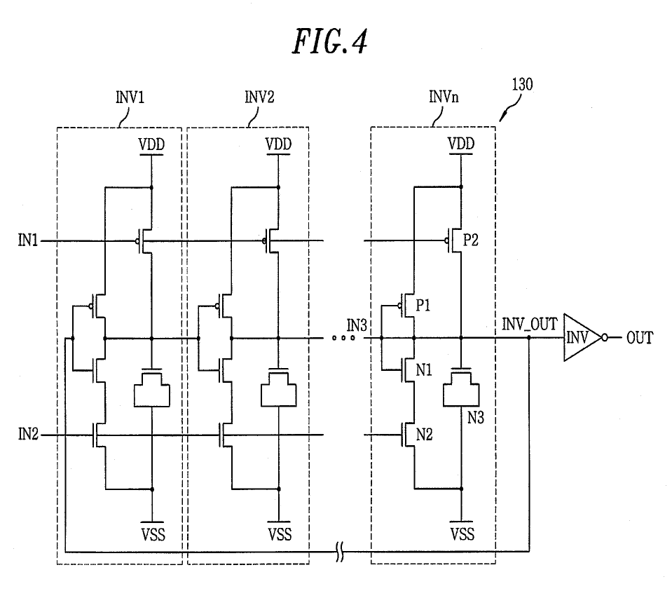

Example FIG. 4 illustrates a circuit diagram of an oscillating unit of example FIG. 3, according to embodiments.

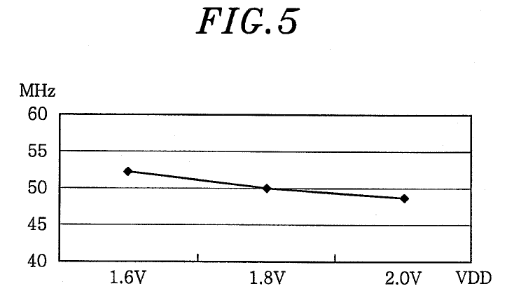

Example FIG. 5 illustrates a simulated waveform of an output frequency from a VCO depending on a first voltage applied to a VCO in example FIG. 4, according to embodiments.

### DESCRIPTION

Example FIG. 3 illustrates a block diagram of a voltage controlled oscillator (VCO) according to embodiments. Referring to example FIG. 3, voltage controlled oscillator (VCO) 100 may include reference voltage generator 110, voltage-current converter 120, and oscillating unit 130. Reference voltage generator 110 may be electrically coupled with voltage-current converter 120, and may be supplied with an external signal through input terminal IN to generate a reference voltage. The reference voltage may be supplied to voltage-current converter 120. Voltage-current converter 120 may be electrically coupled between reference voltage generator 110 and oscillating unit 130, and may be supplied with a reference voltage from reference voltage generator 110. Voltage-current converter 120 may convert the reference voltage into a first current signal and a second current signal, which may be supplied to first input terminal IN1 and second input terminal IN2 of oscillating unit 130. Oscillating unit 130 may be electrically coupled to voltage-current converter 120, and may be supplied with first current at first input terminal IN1 and second current at second input terminal IN2 from voltage-current converter 120. Oscillating unit 130 may output a voltage having a frequency in proportion to first current IN1 and second current IN2 through output terminal OUT.

Example FIG. 4, illustrates a circuit diagram of oscillating unit 130 described in example FIG. 3. Referring to example FIG. 4, oscillating unit 130 may include an odd-number of inverting units. According to embodiments, oscillating unit 130 may include first inverting unit INV1 through n-th inverting unit INVn arranged and coupled in sequence, all of which may have substantially the same configuration. Oscillating unit 130 may include a single inverter INV. Each of inverting units INV1, INV2, . . . , and INVn may be electrically coupled between first voltage source V_{DD} and second voltage source V_{SS}, and may be supplied with a first voltage and a second voltage from first and second voltage sources V_{DD} and V_{SS}. Inverter INV may invert an output signal from n-th inverting unit INVn. The inverted output signal may be outputted through output terminal OUT. Each inverting unit INV1, INV2, . . . , and INVn, may include first through fifth transistors. According to embodiments, each inverting unit INV1, INV2, . . . , and INVn, may include first PMOS transistor P1, second PMOS transistor P2, first NMOS transistor N1, second NMOS transistor N2, and third NMOS transistor N3. First PMOS transistor P1 may include a first electrode (a drain electrode or a source electrode) that may be electrically coupled to first voltage source V_{DD}.

First PMOS transistor P1 may include a second electrode (a source electrode or a drain electrode) that may be electrically coupled between a first electrode of first NMOS transistor N1 and output terminal INV_OUT, and a control electrode (a gate electrode) that may be electrically coupled between third input terminal IN3 and a control electrode of first NMOS transistor N1. First NMOS transistor N1 may include a first electrode that may be electrically coupled between output terminal INV_OUT of inverting unit INVn and the second electrode of first PMOS transistor P1. First NMOS transistor N1 may include a second electrode that may be electrically coupled to a first electrode of second NMOS transistor N2, and a control electrode that may be electrically coupled between third input terminal IN3 and the control electrode of first PMOS transistor P1. First PMOS transistor P1 and first NMOS transistor N1 may be coupled to each other and may function as a switching inverter. Accordingly, first PMOS transistor P1 and first NMOS transistor N1 may provide a current signal having an opposite phase to a current signal from third input terminal IN3 of a preceding converting unit and may output a signal at terminal INV_OUT.

Second PMOS transistor P2 may be connected between first voltage source V_{DD} and output terminal INV_OUT of the switching inverter and may alleviate a ditch induced from a switching operation of the switching inverter. According to embodiments, second PMOS transistor P2 may have a first electrode electrically coupled to first voltage source V_{DD} , a second electrode electrically coupled between output terminal INV_OUT and a control electrode of third NMOS transistor N3, and a control electrode electrically coupled to first input terminal IN1.

According to embodiments, if first NMOS transistor N1 and first PMOS transistor P1 function as an inverter, second PMOS transistor P2 may allow a small current to flow through inverting units INV1, INV2, . . . , and INVn with a voltage supplied from first voltage source V_{DD} even when first PMOS transistor P1 is turned off. According to embodiments, inverting units INV1, INV2, . . . , and INVn may steadily operate with respect to a change of first voltage V_{DD}. Second NMOS transistor N2 may include a first electrode electrically coupled to the second electrode of first NMOS transistor N1, and a second electrode electrically coupled to second voltage source V_{SS}. Second NMOS transistor N2 may include a control electrode electrically coupled to a second input terminal IN2. According to embodiments, second NMOS transistor N2 may function as a current source and may restrict a current to be supplied to first NMOS transistor N1. According to embodiments, if second NMOS transistor N2, which may function as a current source, is installed only between first NMOS transistor N1 and second voltage source V_{SS}, current variation caused by the first voltage supplied from first voltage source V_{DD} may be minimized.

Third NMOS transistor N3 may adjust an oscillating frequency. According to embodiments, third NMOS transistor N3 may include a first electrode electrically coupled to second voltage source V_{SS}, and a second electrode electrically coupled to second voltage source V_{SS}. Third NMOS transistor N3 may include a control electrode electrically coupled to output terminal INV_OUT. According to embodiments, in third NMOS transistor N3, a first electrode and a second electrode may be electrically coupled to second voltage source V_{SS} and may control an oscillating frequency by performing charging and discharging, as if a capacitor, of the current outputted to output terminal INV_OUT of the inverting unit. According to embodiments, third transistor N3 may have a capacitance greater than capacitance of other transistors N1, N2, P1, and P2 of each inverting unit INV1, INV2, . . . , and INVn. Capacitance may be a factor having a large effect on a signal outputted to output terminals INV_OUT of inverting units INV1, INV2, . . . , and INVn.

First input terminal IN1 may be a terminal to which the first current signal supplied from voltage-current converter 120 to oscillating unit 130 is received. Second input terminal IN2 may be a terminal to which the second current signal supplied from voltage-current converter 120 to oscillating unit 130 is received. According to embodiments, first input terminal IN1 and second input terminal IN2 of first inverter INV1 to n-th inverter INVn may be supplied with substantially the same first current signal and substantially the same second current signal. Third input terminal IN3 may be electrically coupled to output terminal INV_OUT of a preceding inverting unit, and may be supplied with an output signal from the preceding inverting unit. According to embodiments, a preceding inverting unit of n-th inverter INVn may be (n-1)-th inverting unit INVn-1. N-th inverter INVn may be coupled such that third input terminal IN3 thereof may be electrically coupled to output terminal INV_OUT of (n-1)-th inverting unit INVn-1. According to embodiments, third input terminal IN3 of first inverting unit INV1 may be electrically coupled to output terminal INV_OUT of n-th inverting unit INVn and may receive an output signal from output terminal INV_OUT of n-th inverting unit INVn.

Example FIG. 5 illustrates a simulated waveform of a frequency of a first voltage from oscillating unit 130 of VCO 100, depicted in example FIG. 4. Referring to example FIG. 5, a simulated waveform of a frequency of a first voltage from oscillating unit 130 of VCO 100 shows a frequency of an output voltage from oscillating unit 130 when a first voltage supplied from first voltage source V_{DD} is changed from 1.6 V to 2.0 V. According to embodiments, when a first voltage supplied from first voltage source V_{DD} is varied, a frequency of an output voltage from oscillating unit 130 may decrease from approximately 52 MHz to approximately 48 MHz. According to embodiments, an output frequency of oscillating unit 130 may vary by approximately 2 MHz as a first voltage supplied from first voltage source V_{DD} varies by approximately 0.2 V. According to embodiments, a variation range of an output frequency of oscillating unit 130 may be less than that of a VCO when a first voltage varies by approximately 0.2 V. Since VCO 100 including oscillating unit 130 may have a frequency variation within approximately 5% of a reference frequency with respect to the variation of the first voltage, a relatively steady output frequency may be output with respect to a variation of the first voltage.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
first and second voltage sources;
a first current source configured to produce a substantially constant current to determine an oscillating frequency;
a switching inverter connected between the first voltage source and the first current source configured to produce an output current having a phase opposite to an input current received from an external source; and
a frequency adjuster configured to control the oscillating frequency by performing at least one of charging and discharging the output current.

2. The device of claim 1, wherein the external source comprises an inverting unit coupled to the switching inverter, and wherein the input current comprises an output current of the inverting unit.

3. The device of claim 2, wherein the input current is an output signal of a final inverter among a plurality of inverters connected in series, and wherein the switching inverter comprises a first inverter among the plurality of inverters.

4. The device of claim 2, wherein the switching inverter comprises:
a first transistor having a control electrode coupled to receive the input current and a first electrode coupled to the first voltage source; and
a second transistor having a control electrode coupled to receive the input current, a first electrode coupled to a second electrode of the first transistor, and a second electrode coupled to the first current source.

5. The device of claim 4, wherein the first transistor comprises a PMOS transistor, and wherein the second transistor comprises an NMOS transistor.

6. The device of claim 4, wherein the frequency adjuster comprises a third transistor having a first electrode coupled to the second voltage source, a second electrode coupled to the second voltage source, and a control electrode coupled to an output terminal of the switching inverter.

7. The device of claim 6, wherein the third transistor comprises an NMOS transistor.

8. The device of claim 4, further comprising a second current source connected between the first voltage source and an output of the switching inverter to alleviate a ditch induced from an operation of the first transistor of the switching inverter.

9. The device of claim 4, wherein the first current source is connected between the first transistor of the inverting unit and the second voltage source to limit the input current to the first transistor.

10. The device of claim 9, wherein the first current source comprises an NMOS transistor.

11. The device of claim 4, further comprising an inverter coupled to receive the output current from the switching inverter.

12. The device of claim 4, wherein the frequency adjuster sequentially charges and discharges the output current.

13. A device comprising:
a first PMOS transistor electrically coupled between a first voltage source and a second voltage source;
a first NMOS transistor electrically coupled between the first PMOS transistor and the second voltage source;
a second NMOS transistor electrically coupled between the first NMOS transistor and the second voltage source;
a second PMOS transistor electrically coupled between the first voltage source and the second voltage source, and coupled to an output terminal of a preceding inverting unit; and
a third NMOS transistor electrically coupled to the second NMOS transistor, and having a control electrode electrically coupled between the first PMOS transistor and the second PMOS transistor, and having first and second electrodes coupled to the second voltage source.

14. The device of claim 13, wherein the second PMOS transistor has a control electrode configured to receive a first current.

15. The device of claim 14, wherein the second NMOS transistor has a control electrode configured to receive a second current.

16. A method comprising:
producing a substantially constant current by a first current source to determine an oscillating frequency;
producing an output current having a phase opposite to an input current received from an external source using a switching inverter connected between a first voltage source and the first current source; and
controlling the oscillating frequency by charging and discharging the output current using a frequency adjuster.

17. The method of claim 16, wherein the input current is received from an inverting unit coupled to the switching inverter, and wherein the input current comprises an output current of the inverting unit.

18. The method of claim 17, wherein producing the output current comprises:
providing a first transistor having a control electrode coupled to receive the input current and a first electrode coupled to the first voltage source; and
providing a second transistor having a control electrode coupled to receive the input current, a first electrode coupled to a second electrode of the first transistor, and a second electrode connected to the first current source.

19. The method of claim 18, wherein controlling the oscillating frequency comprises providing a transistor having a first electrode coupled to the second voltage source, a second electrode coupled to the second voltage source, and a control electrode coupled to an output of the switching inverter.

20. The method of claim 18, further comprising alleviating a ditch induced from an operation of the first transistor of the switching inverter by connecting a second current source between the first voltage source and an output of the switching inverter.
